(19) United States
(12) Patent Application Publication
(10) Pub. No.: US 2026/0372000 A1
(43) Pub. Date: Nov. 19, 2026

(54) SUBSTRATE STORAGE CONTAINER

(71) Applicant: MIRIAL CO., LTD., Tokyo (JP)

(72) Inventor: Ryuuji FUKUDA, Tokyo (JP)

(21) Appl. No.: 19/487,085

(22) PCT Filed: May 25, 2023
(86) PCT No.: PCT/JP2023/019438

§ 371 Date: Nov. 24, 2025

(51) Int. Cl. H10P 72/10

(52) U.S. Cl. CPC H10P 72/1916

(57) ABSTRACT

A lid of a substrate storage container has a seal member which is interposed between an opening peripheral edge part and a peripheral edge part-facing part and which comes into close contact with the opening peripheral edge part and the peripheral edge part-facing part to close a container body opening part in an airtight state. The opening peripheral edge part has a seal surface on which the seal member abuts a rear side of an opening edge of the opening peripheral edge part. The container body has, on the seal surface, a first rib standing in a direction orthogonal to a front-rear direction, and has, at a location spaced apart from the first rib to the rear side, a second rib standing in a direction orthogonal to the front-rear direction. The second rib extends at least over the first side wall, the upper wall, and the second side wall.

### TECHNICAL FIELD

The present invention relates to a substrate storing container that stores substrates such as semiconductor wafers.

### BACKGROUND ART

As a container for storing substrates such as semiconductor wafers, a substrate storing container that includes a container body and a lid has been conventionally known.

The container body includes a tubular wall that has, at one end, an opening peripheral edge portion defining a container body opening, and has the other end closed. The container body has a substrate storing space formed therein. The substrate storing space is formed by being surrounded by the wall and can store a plurality of substrates. The lid is attachable to and detachable from the container body opening and can close the container body opening.

A front retainer is provided at a part of the lid that faces the substrate storing space when the container body opening is closed with the lid. The front retainer can support edge portions of the plurality of substrates when the container body opening is closed with the lid. Furthermore, a back-side substrate support is provided at the wall so as to form a counterpart to the front retainer. The back-side substrate support can support edge portions of the plurality of substrates. When the container body opening is closed with the lid, the back-side substrate support retains, in cooperation with the front retainer, the plurality of substrates in a state in which the adjacent substrates are arranged in parallel and spaced apart from each other by a predetermined interval.

The lid is provided with a sealing member. The sealing member is attached to the lid and extends all along an outer rim of the lid. In a state in which the lid is attached to the container body opening, the sealing member is elastically deformed by being held between a sealing surface of the container body and the inner surface of the lid, and the lid hermetically closes the container body opening. By removing the lid from the opening peripheral edge portion, the substrates can be loaded into and unloaded from the substrate storing space of the container body (see, for example Patent Document 1).

### CITATION LIST

### Patent Documents

Patent Document 1: Japanese Patent No. 3916342.

### DISCLOSURE OF THE INVENTION

### Problems to Be Solved by the Invention

When used to transport the substrates to a site where the substrates are subjected to a process step, the substrate storing container may be conveyed by an overhead hoist transporter (OHT) such as an automatic wafer transport system (e.g., an AMHS) or a wafer substrate transport carriage (e.g., a PGV). At that time, a top flange provided on the upper wall of the container body is gripped, whereby the substrate storing container is suspended. When suspended, the upper wall of the container body bends due to the weight of the substrates stored in the container body and the weight of the substrate storing container. Consequently, the airtightness established by the sealing member is not maintained in an upper portion of the substrate storing container, and a gap is likely to arise between the container body and the lid. In that case, particles intrude into the substrate storing space of the container body through the gap, which would be a possible cause for contamination.

It is an object of the present invention to provide a substrate storing container capable of reducing the likelihood that airtightness established by a sealing member is not maintained in an upper portion of the substrate storing container due to suspension of the substrate storing container.

### Means for Solving the Problems

(1) A first aspect of the present invention is directed to a substrate storing container, which includes: a container body including therein a substrate storing space capable of storing a plurality of substrates, an opening peripheral edge portion defining a container body opening that communicates with the substrate storing space at one end on a forward side, and an opposite end on a rearward side that is closed with a back wall; and a lid attachable to and detachable from the container body opening, capable of closing the container body opening, and including a peripheral-edge-portion facing portion that faces the opening peripheral edge portion. The lid further includes a sealing member that airtightly closes the container body opening by being sandwiched between, and coming into tight contact with, the opening peripheral edge portion and the peripheral-edge-portion facing portion. The container body further includes an upper wall and a lower wall that face each other, a first side wall and a second side wall that face each other, and the back wall to which a rear end of the upper wall, a rear end of the lower wall, a rear end of the first side wall, and a rear end of the second side wall are connected. A front end of the upper wall, a front end of the lower wall, a front end of the first side wall, and a front end of the second side wall form the opening peripheral edge portion. The opening peripheral edge portion has a sealing surface with which the sealing member comes into contact, at a position on the rearward side with respect to an opening edge of the opening peripheral edge portion. The container body has a first rib, which stands in a direction orthogonal to a forward-rearward direction, at the sealing surface, and a second rib, which stands in a direction orthogonal to the forward-rearward direction, at a position spaced apart from the first rib toward the rearward side. The second rib extends at least over the first side wall, the upper wall, and the second side wall.
(2) According to a second aspect of the present invention, in the substrate storing container described in (1) above, the container body further includes a hanging part by means of which the substrate storing container is suspended, and the second rib is disposed between the first rib and the hanging part in the forward-rearward direction.
(3) According to a third aspect of the present invention, in the substrate storing container described in (1) or (2) above, the upper wall that is located at a base portion of the second rib includes a stepped portion which is oriented toward the rearward side and recesses inward in a direction orthogonal to the forward-rearward direction.
(4) According to a fourth aspect of the present invention, in the substrate storing container described in any one of (1) to (3) above, a position of a top of the first rib and a position of a top of the second rib are identical with each other in a direction orthogonal to the forward-rearward direction.
(5) According to a fifth aspect of the present invention, in the substrate storing container described in any one of (1) to (4) above, a distance between the first rib and the second rib in the forward-rearward direction is 10 mm to 50 mm.
(6) According to a sixth aspect of the present invention, in the substrate storing container described in any one of (1) to (5) above, the second rib extends over the first side wall, the upper wall, the second side wall, and the lower wall.

### Effects of the Invention

The present invention can provide a substrate storing container capable of reducing the likelihood that the airtightness established by a sealing member is not maintained in an upper portion of the substrate storing container due to suspension of the substrate storing container.

### BRIEF DESCRIPTION OF THE DRAWINGS

FIG. 1 is an exploded perspective view illustrating a substrate storing container 1 according to an embodiment of the present invention;

FIG. 2 is an exploded perspective view illustrating a state in which substrates W are stored in the substrate storing container 1 according to the embodiment of the present invention;

FIG. 3 is a perspective view of a lid 3 of the substrate storing container 1 according to the embodiment of the present invention, and illustrates a state in which the lid 3 has a sealing member 4 and a front retainer 7 attached thereto;

FIG. 4 is a perspective view illustrating the sealing member 4 of the lid 3 of the substrate storing container 1 according to the embodiment of the present invention;

FIG. 5 is a top view illustrating a container body 2 of the substrate storing container 1 according to the embodiment of the present invention;

FIG. 6 is a rear view illustrating the container body 2 of the substrate storing container 1 according to the embodiment of the present invention;

FIG. 7A is a vertical cross-sectional view of the substrate storing container 1 according to the embodiment of the present invention, taken along a center in a left-right direction; and

FIG. 7B is a partial enlarged view of the sealing member 4 and the vicinity thereof in FIG. 7A.

### PREFERRED MODE FOR CARRYING OUT THE INVENTION

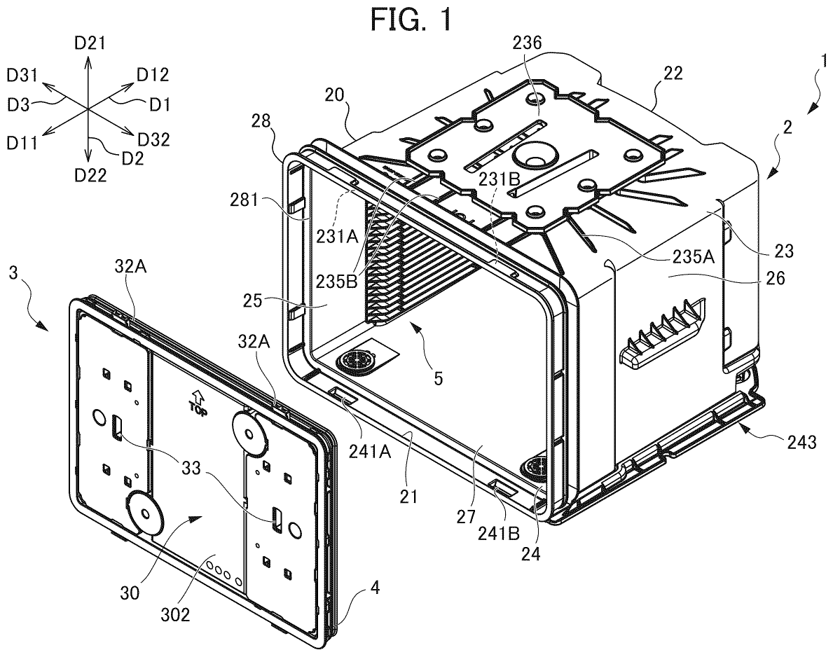

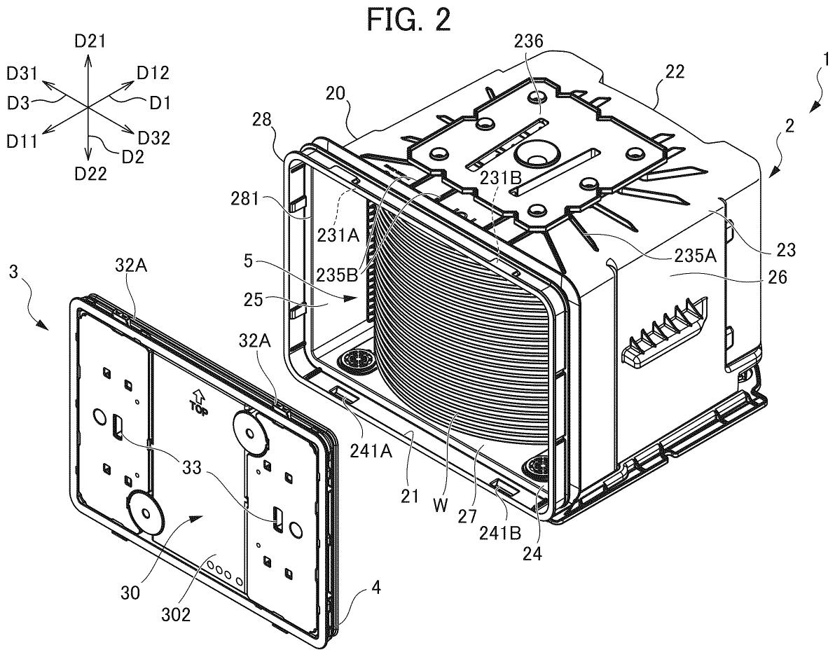

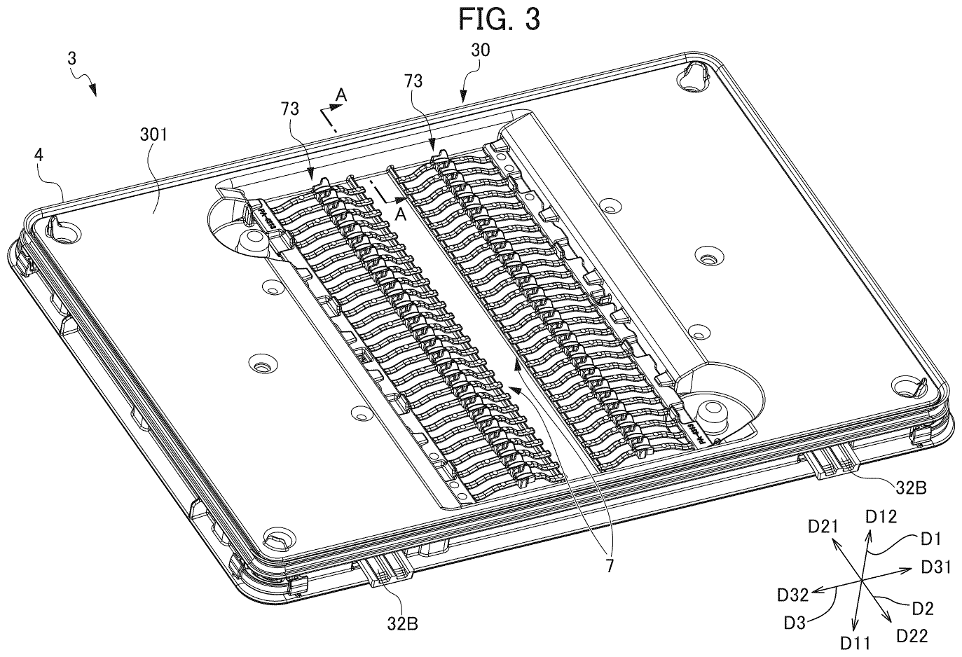

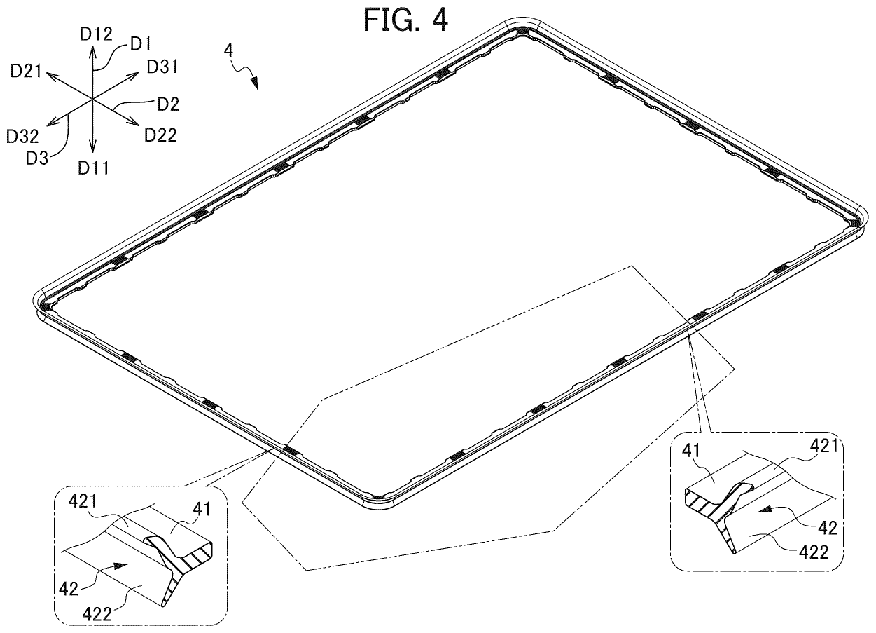

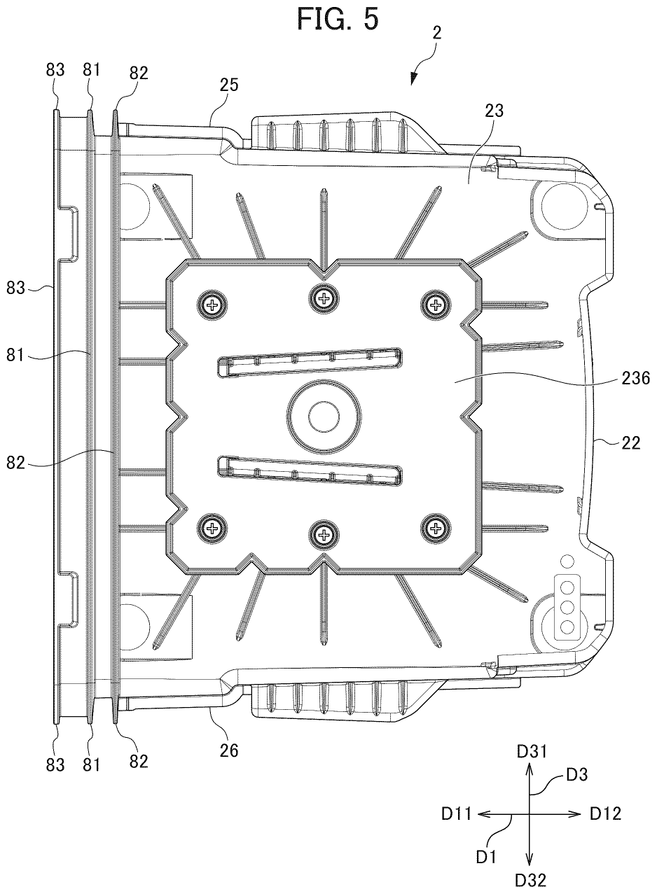

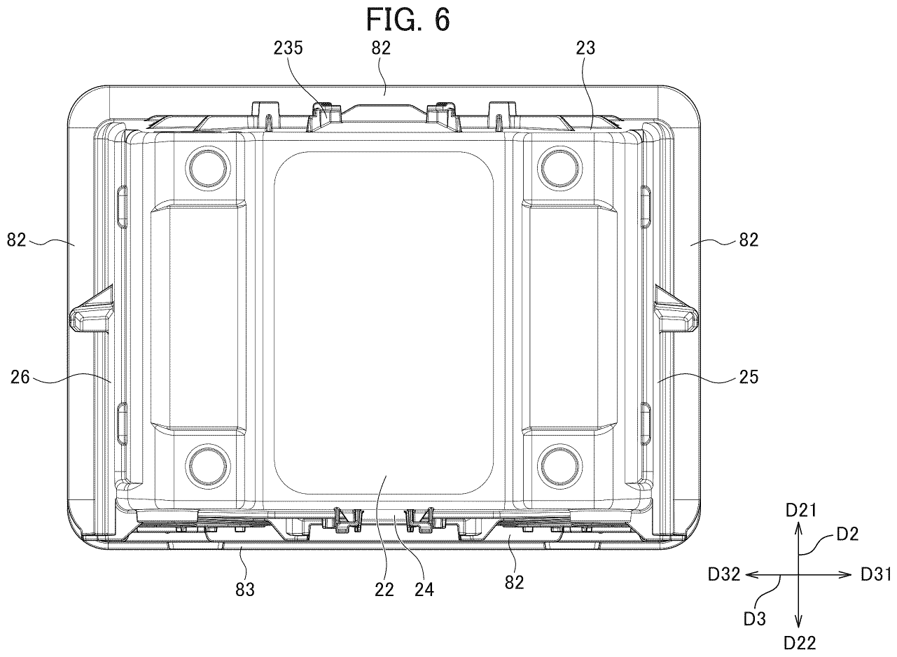

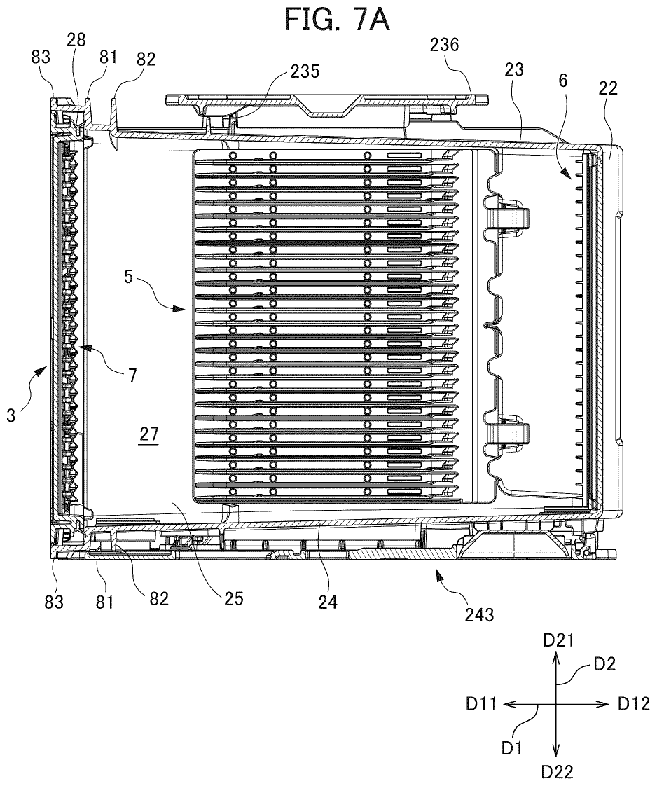

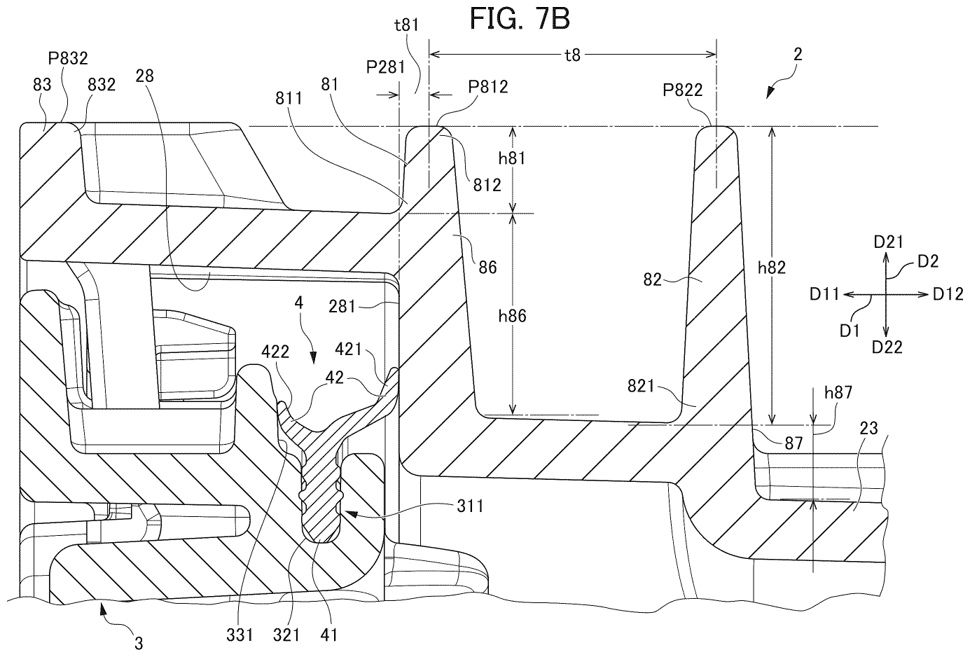

A substrate storing container 1 according to an embodiment of the present invention will be described below with reference to the drawings. FIG. 1 is an exploded perspective view illustrating the substrate storing container 1 according to the embodiment of the present invention. FIG. 2 is an exploded perspective view illustrating a state in which substrates W are stored in the substrate storing container 1 according to the embodiment of the present invention. FIG. 3 is a perspective view of a lid 3 of the substrate storing container 1 according to the embodiment of the present invention, and illustrates a state in which the lid 3 has a sealing member 4 and a front retainer 7 attached thereto. FIG. 4 is a perspective view illustrating the sealing member 4 of the lid 3 of the substrate storing container 1 according to the embodiment of the present invention. FIG. 5 is a top view illustrating a container body 2 of the substrate storing container 1 according to the embodiment of the present invention. FIG. 6 is a rear view illustrating the container body 2 of the substrate storing container 1 according to the embodiment of the present invention. FIG. 7A is a vertical cross-sectional view of the substrate storing container 1 according to the embodiment of the present invention, taken along a center in a left-right direction. FIG. 7B is a partial enlarged view of the sealing member 4 and the vicinity thereof in FIG. 7A.

For convenience of description, the direction from a container body 2 toward a lid 3 (described later) (a direction from upper right to lower left in FIG. 1) is defined as a forward direction D11, and the direction opposite to the direction D11 is defined as a rearward direction D12. Furthermore, these directions are defined as a forward-rearward direction D1. In addition, the direction from a lower wall 24 to an upper wall 23 (described later) (upward direction in FIG. 1) is defined as an upward direction D21, and the direction opposite to the direction D21 is defined as a downward direction D22. Furthermore, these directions are defined as an upward-downward direction D2. Moreover, the direction from a second side wall 26 to a first side wall 25 (described later) (a direction from lower right to upper left in FIG. 1) is defined as a left direction D31, and the direction opposite to the direction D31 is defined as a right direction D32. Furthermore, these directions are defined as a left-right direction D3 or a lateral direction D3. The “direction” may be referred to as “side”.

The substrates W (see FIG. 2) stored in the substrate storing container 1 are thin substrates for industrial use, and examples thereof include disk-shaped silicon wafers, disk-shaped glass wafers, and disk-shaped sapphire wafers. Each substrate W of the present embodiment is a silicon wafer having a diameter of 200 mm to 450 mm.

As illustrated in FIGS. 1 to 7A, a substrate storing container 1 is for storing substrates W each made of the silicon wafer described above, and includes a container body 2, a lid 3, substrate support plate-like portions 5 as side substrate supports, a back-side substrate support 6 (see FIG. 7A), and a front retainer 7 as a lid-side substrate support.

As illustrated in FIG. 1, the container body 2 includes a tubular wall 20 having a container body opening 21 formed at one end thereof and having the other end closed. The container body 2 has a substrate storing space 27 formed therein. The substrate storing space 27 is surrounded and defined by the wall 20. The substrate support plate-like portions 5 are disposed on portions of the wall 20 that define the substrate storing space 27. As illustrated in FIG. 2, the substrate storing space 27 can store therein the plurality of substrates W.

The substrate support plate-like portions 5 are provided on the wall 20 so as to form counterparts to each other in the left-right direction D3 in the substrate storing space 27. When the container body opening 21 is not closed with the lid 3, the substrate support plate-like portions 5 contact with side portions of edge portions of the plurality of substrates W to thereby support the side portions of the edge portions of the plurality of substrates W in a state in which adjacent substrates W are arranged in parallel with and spaced apart from each other by a predetermined interval. The back-side substrate support 6 is provided on the back side of the substrate support plate-like portions 5.

The back-side substrate support 6 is provided on the wall 20 so as to form a counterpart to the front retainer 7 in the substrate storing space 27. When the container body opening 21 is closed with the lid 3, the back-side substrate support 6 can support rear portions of the edge portions of the plurality of substrates W by contacting with the rear portions of the edge portions of the plurality of substrates W.

The lid 3 is attachable to and detachable from an opening peripheral edge portion 28 that defines the container body opening 21, and can close the container body opening 21. The front retainer 7 is provided on a part of the lid 3 that faces the substrate storing space 27 when the container body opening 21 is closed with the lid 3. The front retainer 7 is disposed so as to form a counterpart to the back-side substrate support 6 in the forward-rearward direction D1 in the substrate storing space 27.

When the container body opening 21 is closed with the lid 3, the front retainer 7 can support front portions of the edge portions of the plurality of substrates W by contacting with the edge portions of the plurality of substrates W. When the container body opening 21 is closed with the lid 3, the front retainer 7 cooperates with the back-side substrate support 6 to hold the plurality of substrates W in a state in which the adjacent substrates W are arranged in parallel with and spaced apart from each other by a predetermined interval. Hereinafter, each component will be described in detail.

As illustrated in FIG. 1, etc., the wall 20 of the container body 2 includes a back wall 22, an upper wall 23, a lower wall 24, a first side wall 25, and a second side wall 26. The back wall 22, the upper wall 23, the lower wall 24, the first side wall 25, and the second side wall 26 can be made of a plastic material, etc., and are configured as a one-piece molding of polycarbonate in the present embodiment.

The first side wall 25 faces the second side wall 26, and the upper wall 23 faces the lower wall 24. A rear end of the upper wall 23, a rear end of the lower wall 24, a rear end of the first side wall 25, and a rear end of the second side wall 26 are all connected to the back wall 22. A front end of the upper wall 23, a front end of the lower wall 24, a front end of the first side wall 25, and a front end of the second side wall 26 each have a positional relationship of being opposite to the back wall 22, and form the opening peripheral edge portion 28 that defines the container body opening 21 having a substantially rectangular shape.

The opening peripheral edge portion 28 is provided at one end of the container body 2 on the forward side D11, and the back wall 22 is located at the other end of the container body 2 on the rearward side D12. The outer shape of the container body 2 formed with the outer surface of the wall 20 is a box shape. The inner surface of the wall 20, that is, the inner surface of the back wall 22, the inner surface of the upper wall 23, the inner surface of the lower wall 24, the inner surface of the first side wall 25, and the inner surface of the second side wall 26 surround and define the substrate storing space 27. The container body opening 21 defined by the opening peripheral edge portion 28 communicates with the substrate storing space 27 that is surrounded with the wall 20 and formed in the container body 2. The substrate storing space 27 can store a maximum of twenty-five substrates W.

As illustrated in FIGS. 1 and 2, latch engagement concave portions 231A, 231B, 241A, and 241B, which are concave outwardly from the substrate storing space 27, are formed at portions of the upper wall 23 and the lower wall 24 which are proximal to the opening peripheral edge portion 28. A total of four latch engagement concave portions 231A, 231B, 241A, and 241B are formed in proximity to the left and right ends of the upper wall 23 and the left and right ends of the lower wall 24, on a one-to-one basis.

On the outer surface of the upper wall 23, a flange fixing portion 235 (see FIG. 7A) and ribs 235A and 235B are integrally formed with the upper wall 23. The flange fixing portion 235 is disposed on a center portion of the upper wall 23. A top flange 236 serving as a hanging part is fixed to the flange fixing portion 235. The top flange 236 is disposed at the center portion of the upper wall 23. The top flange 236 is a member by means of which the substrate storing container 1 is suspended by an overhead hoist transporter (OHT) such as an automatic wafer transport system (e.g., AMHS) or a wafer substrate transport carriage (e.g., PGV).

Some of the ribs 235A extend approximately in the left direction D31 from the top flange 236, and the others of the ribs 235A extend approximately in the right direction D32 from the top flange 236. Some of the ribs 235B extend in the forward direction D11 from the top flange 236, and the others of the ribs 235B extend in the rearward direction D12 from the top flange 236.

As illustrated in FIGS. 1 and 7A, a container body leg 243 is provided on the outer surface of the lower wall 24. The container body leg 243 is integrally formed with left and right edges of the lower wall 24, and extends in the forward-rearward direction D1 along the left and right edges of the lower wall 24. When the container body 2 is placed on a horizontal flat surface with the lower wall 24 facing the downward side D22, the container body leg 243 is in contact with the flat surface and stably supports the container body 2.

The lid 3 is provided with a latch mechanism. The latch mechanism is provided in proximity to the left and right ends of the lid 3. As illustrated in FIGS. 1 and 2, the latch mechanism includes two upper latch parts 32A that can protrude from the upper side of the lid 3 in the upward direction D21, and two lower latch parts 32B that can protrude from the lower side of the lid 3 in the downward direction D22. The two upper latch parts 32A are disposed respectively in proximity to the left and right ends of the upper side of the lid 3, and the two lower latch parts 32B are disposed respectively in proximity to the left and right ends of the lower side of the lid 3.

The outer surface of the lid 3 is provided with operation parts 33. Manipulating the operation parts 33 from the front side of the lid 3 causes the upper latch parts 32A and the lower latch parts 32B not only to protrude respectively from the upper side and the lower side of the lid 3 but also to hold not protruded respectively from the upper side and the lower side of the lid 3. The upper latch parts 32A protrude from the upper side of the lid 3 in the upward direction D21 to engage with the latch engagement concave portions 231A, 231B of the container body 2, and the lower latch parts 32B protrude from the lower side of the lid 3 in the downward direction D22 to engage with the latch engagement concave portions 241A, 241B of the container body 2, whereby the lid 3 is fastened to the opening peripheral edge portion 28 of the container body 2.

The front retainer 7 is fixed to the inner side of a lid body 30 of the lid 3. In the present embodiment, the front retainer 7 is composed of parts separate from each other in the left-right direction D3. The front retainer 7 has front-retainer substrate receiving portions 73. The front-retainer substrate receiving portions 73 are arranged such that two front-retainer substrate receiving portions 73 form a pair while being spaced apart from each other in the left-right direction D3 by a predetermined distance. In this way, twenty-five pairs of front-retainer substrate receiving portions 73 are arranged to form two lines arranged side-by-side and extending in the upward-downward direction D2. When the substrates W are stored in the substrate storing space 27 and the lid 3 is closed, the front-retainer substrate receiving portions 73 clamp ends of the edge portions of the substrates W.

As illustrated in FIGS. 1 to 4, the lid 3 has a substantially rectangular shape that substantially coincides with the shape of the opening peripheral edge portion 28 of the container body 2. The lid 3 is attachable to and detachable from the opening peripheral edge portion 28 of the container body 2. By attaching the lid 3 to the opening peripheral edge portion 28, the container body opening 21 can be closed with the lid 3. The sealing member 4 having a looped shape is attached to a peripheral-edge-portion facing portion 331 that forms part of an inner surface 301 (back surface) of the lid 3. When the lid 3 closes the container body opening 21, the peripheral-edge-portion facing portion 331 faces a surface (sealing surface 281) of a stepped portion (first stepped portion 86 to be described later) that is formed at a position on the rearward side D12 immediately behind the opening edge of the opening peripheral edge portion 28. In other words, the opening peripheral edge portion 28 has the sealing surface 281 with which the sealing member 4 contacts, at the position on the rearward side D12 behind the opening edge of the opening peripheral edge portion 28.

As illustrated in FIG. 7B, when the lid 3 is attached to the opening peripheral edge portion 28, a lip portion 42 of the sealing member 4 is elastically deformed by being sandwiched between the sealing surface 281 of the opening peripheral edge portion 28 and the peripheral-edge-portion facing portion 331 forming part of the inner surface 301 of the lid 3, and the lid 3 hermitically closes the container body opening 21. When the lid 3 is detached from the opening peripheral edge portion 28, a substrate W can be loaded into and unloaded from the substrate storing space 27 in the container body 2.

More specifically, the lid 3 includes the lid body 30. The lid body 30 forms the contour of the lid 3 having a substantially rectangular shape. Accordingly, the lid body 30 has a substantially rectangular shape. The lid body 30 has the inner surface 301 and an outer surface 302. The inner surface 301 faces the substrate storing space 27 when the lid 3 closes the container body opening 21. The outer surface 302 is exposed outside the substrate storing container 1 when the lid 3 closes the container body opening 21. The lid body 30 is made of a plastic material, etc., and is configured as a molding of polycarbonate in the present embodiment.

As illustrated in FIG. 7B, a rim of the lid body 30, which faces the sealing surface 281 forming the opening peripheral edge portion 28 of the container body 2, includes a sealing member attachment portion 311 and the peripheral-edge-portion facing portion 331. The sealing member attachment portion 311 has a retaining groove 321 formed therein. The sealing member attachment portion 311 extends all along the rim of the lid body 30. The retaining groove 321 also extends all along the rim of the lid body 30, and along the sealing member attachment portion 311. The peripheral-edge-portion facing portion 331 is formed of a portion of the rim of the lid body 30 that faces the sealing surface 281 forming part of the opening peripheral edge portion 28, the portion being located more outside the lid 3 than the retaining groove 321. The peripheral-edge-portion facing portion 331 is formed of a plate-shaped portion which forms part of the rim of the lid body 30 and extends in a D2-D3 plane (which is perpendicular to the forward-rearward direction D1).

The retaining groove 321 receives a base portion 41 (to be described later) of the sealing member 4 inserted therein. In this way, the sealing member 4 is attached to the sealing member attachment portion 311 of the lid 3, and the lip portion 42 of the sealing member 4 can come into contact with the sealing surface 281 of the opening peripheral edge portion 28 and the peripheral-edge-portion facing portion 331.

The sealing member 4 is made of various elastically deformable thermoplastic elastomers such as polyester-based elastomers, polyolefin-based elastomers, and the like, fluorine rubber, and silicon rubber, etc. As illustrated in FIG. 4, the sealing member 4 has a rectangular and looped shape and is arranged so as to extend all along an outer rim of the lid 3.

The sealing member 4 includes the base portion 41 and the lip portion 42. The base portion 41 is inserted into the retaining groove 321. The lip portion 42 is formed integrally with a base end of the base portion 41. The lip portion 42 extends from the base end of the base portion 41 in a direction oblique to the direction in which the base portion 41 extends. As illustrated in FIGS. 4 and 7B, the lip portion 42 branches at a middle thereof into two parts, namely, a peripheral edge portion contacting lip 421 and a facing portion contacting lip 422. When the lid 3 closes the container body opening 21, the peripheral edge portion contacting lip 421 is in contact with the sealing surface 281 of the opening peripheral edge portion 28 of the container body 2, whereas the facing portion contacting lip 422 is in contact with the peripheral-edge-portion facing portion 331.

Here, an area of the lid 3 on the upward side D21, which is illustrated in FIG. 7B, will be described as an example. The peripheral edge portion contacting lip 421 extends in an oblique direction (an outward direction with respect to a D2-D3 plane) between the rearward direction D12 and the upward direction D21 so as to come into contact with the sealing surface 281 of the opening peripheral edge portion 28. The facing portion contacting lip 422 extends in an oblique direction (an outward direction with respect to the D2-D3 plane) between the forward direction D11 and the upward direction D21 so as to come into contact with the peripheral-edge-portion facing portion 331. Although the direction in which the peripheral edge portion contacting lip 421 extends and the direction in which the facing portion contacting lip 422 extends vary depending on the position of the sealing member 4 on the lid 3, the directions can generally be referred to as outward directions with respect to the D2-D3 plane.

Due to the contact of the peripheral edge portion contacting lip 421 with the opening peripheral edge portion 28 and the contact of the facing portion contacting lip 422 with the peripheral-edge-portion facing portion 331, the lip portion 42 of the sealing member 4 is sandwiched to be in tight contact with the opening peripheral edge portion 28 and the peripheral-edge-portion facing portion 331, whereby the lip portion 42 airtightly closes the container body opening 21 in cooperation with the lid 3.

Next, ribs provided on the outer surface of the container body 2 will be described. The following description is provided with refence to the area of the lid 3 on the upward side D21, which is illustrated in FIG. 7B, as an example. The container body 2 has a third rib 83, a first rib 81, and a second rib 82 on the outer surface in this order in the direction from the forward side D11 toward the rearward side D12. The first rib 81 is disposed at a position P281 of the sealing surface 281 of the opening peripheral edge portion 28, and stands outward in a direction (a direction along the plane D2-D3) orthogonal to the forward-rearward direction D1. The first rib 81 extends at least over the first side wall 25, the upper wall 23, and the second side wall 26. The first rib 81 of the present embodiment extends circumferentially over the entire circumference formed of the first side wall 25, the upper wall 23, the second side wall 26, and the lower wall 24. Typically, the first rib 81 stands in the upward direction D21, the left direction D31, the right direction D32, and the downward direction D2.

The phrase “the first rib 81 is located at the position P281 of the sealing surface 281”, that is, “the container body 2 has the first rib 81 at the position P281 of the sealing surface 281” means that, as illustrated in FIG. 7B, a distance t81 from the center of a base portion 811 of the first rib 81 to the position P281 of the sealing surface 281 in the forward-rearward direction D1 is, for example, within a range of 10 mm, and preferably within a range of 5 mm in each of the forward and rearward directions. The first rib 81 has a height h81 of 0.5 mm or more and 15 mm or less, and preferably 3 mm or more and 8 mm or less.

The second rib 82 is disposed at a position spaced apart from the first rib 81 toward the rearward side D12, and stands outward in a direction (a direction along the plane D2-D3) orthogonal to the forward-rearward direction D1. The second rib 82 extends at least over the first side wall 25, the upper wall 23, and the second side wall 26. The second rib 82 of the present embodiment extends circumferentially over the entire circumference formed of the first side wall 25, the upper wall 23, the second side wall 26, and the lower wall 24. Typically, the second rib 82 stands in the upward direction D21, the left direction D31, the right direction D32, and the downward direction D22.

In the forward-rearward direction D1, a distance to (center-to-center distance) between the first rib 81 and the second rib 82 is, for example, 5.0 mm or more and 60 mm or less, preferably 10 mm or more and 50 mm or less, and more preferably 15 mm or more and 30 mm or less. The second rib 82 has a height h82 of, for example, 10 mm or more and 30 mm or less, and preferably 15 mm or more and 25 mm or less.

The upper wall 23 located at the base portion 811 of the first rib 81 has a first stepped portion 86 that recesses toward the rearward side D12 and inward with respect to a direction orthogonal to the forward-rearward direction D1 (direction along the D2-D3 plane). Specifically, a region of the upper wall 23 located on the rearward side D12 with respect to the first rib 81 is provided with the first stepped portion 86 having a height difference h86. The step direction (recess direction) of the first stepped portion is typically the downward direction D22, the right direction D32, the left direction D31, and the upward direction D21. The height difference h86 of the first stepped portion 86 is, for example, 5.0 mm or more and 25 mm or less, and preferably 10 mm or more and 20 mm or less.

A region of the upper wall 23 located on the rearward side D12 with respect to the second rib 82 is provided with a second stepped portion 87 having a height difference h87. The step direction (recess direction) of the second stepped portion is typically the downward direction D22, the right direction D32, the left direction D31, and the upward direction D21. The height difference h87 of the second stepped portion 87 is, for example, 1.0 mm or more and 10 mm or less, and preferably 3.0 mm or more and 7.0 mm or less.

In the direction orthogonal to the forward-rearward direction D1 (direction along the D2-D3 plane), a position P812 of a top 812 of the first rib 81, a position P822 of a top 822 of the second rib 82, and a position P832 of a top 832 of the third rib 83 are similar to each other. Here, “similar to” means that a difference in position in the upward-downward direction D2 is, for example, 5.0 mm or less, and preferably 1.0 mm or less.

The third rib 83 is disposed at a foremost position of the container body 2 and stands outward in a direction orthogonal to the forward-rearward direction D1 (a direction along the D2-D3 plane). The third rib 83 extends at least over the first side wall 25, the upper wall 23, and the second side wall 26. The third rib 83 of the present embodiment extends circumferentially over the entire circumference formed of the first side wall 25, the upper wall 23, the second side wall 26, and the lower wall 24. Typically, the third rib 83 stands in the upward direction D21, the left direction D31, the right direction D32, and the downward direction D22.

The first rib 81, the second rib 82, the third rib 83, the first stepped portion 86, and the second stepped portion 87 that are disposed in the region of the container body 2 on the upward side D21 have been described in the foregoing. It should be noted that regions of the container body 2 on the left side D31, the right side D32, and the downward side D22 are also provided with the first rib 81, the second rib 82, the third rib 83, the first stepped portion 86, and the second stepped portion 87 having basically the same configuration. The configurations and the numerical ranges described in connection with the region on the upward side D21 also apply to the regions on the left side D31, the right side D32, and the downward side D22. The container body leg 243 is provided on the downward side D22. In order to avoid interference with the container body leg 243, the shapes of the first rib 81 and the second rib 82 on a region on the downward side D22 are different from the shapes of the first rib 81 and the second rib 82 on another region on the upward side D21.

As illustrated in FIG. 7A, the second rib 82 is disposed between the first rib 81 and the top flange 236 (hanging part) in the forward-rearward direction D1. That is, when viewed in top view, the second rib 82 does not overlap with the top flange 236.

The substrate storing container 1 of the embodiment having the above-described configuration exerts the following effects. The substrate storing container 1 according to the embodiment includes: the container body 2 including therein the substrate storing space 27 capable of storing the plurality of substrates W, the opening peripheral edge portion 28 defining the container body opening 21 that communicates with the substrate storing space 27 at one end on the forward side D11, and an opposite end on the rearward side D12 that is closed with the back wall 22; and the lid 3 attachable to and detachable from the container body opening 21, capable of closing the container body opening 21, and including the peripheral-edge-portion facing portion 331 that faces the opening peripheral edge portion 28. The lid 3 further includes the sealing member 4 that airtightly closes the container body opening 21 by being sandwiched between, and coming into tight contact with the opening peripheral edge portion 28 and the peripheral-edge-portion facing portion 331. The container body 2 further includes the upper wall 23 and the lower wall 24 that face each other, the first side wall 25 and the second side wall 26 that face each other, and the back wall 22 to which a rear end of the upper wall 23, a rear end of the lower wall 24, a rear end of the first side wall 25, and a rear end of the second side wall 26 are connected. The front end of the upper wall 23, the front end of the lower wall 24, the front end of the first side wall 25, and the front end of the second side wall 26 form the opening peripheral edge portion 28. The opening peripheral edge portion 28 has the sealing surface 281, with which the sealing member 4 comes into contact, at a position on the rearward side D12 with respect to the opening edge of the opening peripheral edge portion 28. The container body 2 has the first rib 81, which stands in a direction (D2-D3) orthogonal to the forward-rearward direction D1, at the sealing surface 281, and the second rib 82, which stands in a direction orthogonal to the forward-rearward direction, at a position spaced apart from the first rib 81 toward the rearward side D12, and the second rib 82 extends at least over the first side wall 25, the upper wall 23, and the second side wall 26.

When used to transport the substrates to a site where the substrates are subjected to a process step, the substrate storing container 1 is conveyed by an overhead hoist transporter (OHT) while being gripped and suspended at the top flange 236 (hanging part) provided on the upper wall 23 of the container body 2. The substrate storing container 1 of the present embodiment includes the second rib 82 that is disposed at a position spaced apart from the first rib 81 toward the rearward side D12, stands in the direction (D2-D3) orthogonal to the forward-rearward direction D1, and extends at least over the first side wall 25, the upper wall 23, and the second side wall 26. Accordingly, the region of the upper wall 23 corresponding to the opening peripheral edge portion 28 is reinforced (increase in rigidity) by the second rib 82, and is difficult to bend. Accordingly, when the substrate storing container 1 is suspended, the upper wall 23 of the container body 2 is less likely to bend (less likely to deform) due to the weight of the substrates W stored in the container body 2 and the weight of the substrate storing container 1. In this manner, a gap is less likely to be generated between the opening peripheral edge portion 28 and the sealing member 4, and the airtightness established by the sealing member 4 is easily maintained in the upper portion of the substrate storing container 1. As a result, it is possible to reduce the likelihood that particles intrude into the substrate storing space 27 of the container body 2 through the gap and cause contamination. In addition, the environment inside the substrate storing space 27 improved with the purged N₂ (nitrogen) is easily maintained. That is, the present embodiment makes it possible to reduce the likelihood that the airtightness established by the sealing member 4 is not maintained in the upper portion of the substrate storing container 1 due to suspension of the substrate storing container 1.

The second rib 82 is disposed between the first rib 81 and the top flange 236 (hanging part) in the forward-rearward direction D1. In a hypothetical case where a rib is disposed under the top flange 236 on the downward side D22, it could be necessary that the top flange 236 is arranged much higher on the upward side D21 than the upper wall 23 in order to avoid interference with the rib. However, this arrangement increases the height of the entire container body 2 including the top flange 236, which will result in an unnecessary increase in the size of the entire substrate storing container 1. In contrast, in the present embodiment, the second rib 82 is disposed between the first rib 81 and the top flange 236 (hanging part). Accordingly, the present embodiment makes it possible to prevent the situation in which the substrate storing container 1 has an unnecessarily large size due to the top flange 236 arranged upward on the upward side D21 to avoid the interference with the second rib 82.

In the present embodiment, the upper wall 23 that is located at the base portion 821 of the second rib 82 has the second stepped portion 87 which is oriented toward the rearward side D12 and recesses inward in a direction (D2-D3) orthogonal to the forward-rearward direction D1. That is, the base portion 821 of the second rib 82 is located inward in the direction (D2-D3) orthogonal to the forward-rearward direction D1, compared with the base portion 811 of the first rib 81. It may be often necessary that the base portion 811 of the first rib 81 is disposed relatively outside in the direction (D2-D3) orthogonal to the forward-rearward direction D1 depending on the size of the lid 3 and the size of the opening peripheral edge portion 28. For this reason, it may be sometimes difficult that the first rib 81 is designed to have a large height h81. In contrast, the base portion 821 of the second rib 82 can be disposed inward in the direction (D2-D3) orthogonal to the forward-rearward direction D1. As a result, the second rib 82 can be configured to have a large height h82, so that it is possible for the second rib 82 to enhance the effects as described above, such as structural reinforcement (increase in rigidity) and reduction in bending.

In the present embodiment, the position P812 of the top 812 of the first rib 81 and the position P822 of the top 822 of the second rib 82 are identical with each other in the direction (D2-D3) orthogonal to the forward-rearward direction D1. This positional relationship is established at least on the upward side D21, the left side D31, and the right side D32. This configuration makes it possible to increase the height h82 of the second rib 82 within a range in which the height or the width in the lateral direction D3 of the entire container body 2 is not unnecessarily increased.

In the present embodiment, the second rib 82 extends over the first side wall 25, the upper wall 23, the second side wall 26, and the lower wall 24. Accordingly, the second rib 82 goes around the container body (resulting in a closed form) in the direction (D2-D3) orthogonal to the forward-rearward direction D1. For this reason, the second rib 82 is further less likely to deform, thereby making it possible to improve the effects described above, such as the structural reinforcement (increase in rigidity) and the reduction in bending of the second rib 82.

It should be noted that the present invention is not limited to the above-described embodiments, and can be modified within the technical scope described in the claims.

The above embodiment includes one second rib 82, but the present invention is not limited thereto, and the two or more second ribs 82 may be provided.

For example, in the above embodiment, the base portion 41 of the sealing member 4 is held by the sealing member attachment portion 311 while being inserted into the retaining groove 321, but the base portion 41 of the sealing member 4 may be held by the sealing member attachment portion 311 in a different mode. For example, the base portion 41 of the sealing member 4 may be held by the sealing member attachment portion 311 while being pinched or engaged.

The shapes of the container body 2 and the lid 3, and the number and dimensions of the substrates W that can be stored in the container body 2 are not limited to those described in the above embodiment.

### EXPLANATION OF REFERENCE NUMERALS

1: Substrate storing container
2: Container body
21: Container body opening
22: Back wall
23: Upper wall
236: Top flange (hanging part)
24: Lower wall
25: First side wall
26: Second side wall
27: Substrate storing space
28: Opening peripheral edge portion
281: Sealing surface
Lid: 3
331: Peripheral-edge-portion facing portion
4: Sealing member
81: First rib
811: Top
812: Base portion
82: Second rib
821: Top
822: Base portion
86: First stepped portion (stepped portion)
P281: Position
P811: Position
P812: Position
D1: Forward-rearward direction
D11: Forward side
D12: Rearward side
D2-D3: Direction orthogonal to frontward-rearward direction
W: Substrate

1. A substrate storing container comprising:
a container body including therein a substrate storing space capable of storing a plurality of substrates, an opening peripheral edge portion defining a container body opening that communicates with the substrate storing space at one end on a forward side, and an opposite end on a rearward side that is closed with a back wall; and
a lid attachable to and detachable from the container body opening, capable of closing the container body opening, and including a peripheral-edge-portion facing portion that faces the opening peripheral edge portion, wherein
the lid further includes a sealing member that airtightly closes the container body opening by being sandwiched between, and coming into tight contact with, the opening peripheral edge portion and the peripheral-edge-portion facing portion,
the container body further includes an upper wall and a lower wall that face each other, a first side wall and a second side wall that face each other, and the back wall to which a rear end of the upper wall, a rear end of the lower wall, a rear end of the first side wall, and a rear end of the second side wall are connected,
a front end of the upper wall, a front end of the lower wall, a front end of the first side wall, and a front end of the second side wall form the opening peripheral edge portion,
the opening peripheral edge portion has a sealing surface, with which the sealing member comes into contact, at a position on the rearward side with respect to an opening edge of the opening peripheral edge portion,
the container body has a first rib, which stands in a direction orthogonal to a forward-rearward direction, at the sealing surface, and a second rib, which stands in a direction orthogonal to the forward-rearward direction, at a position spaced apart from the first rib toward the rearward side, and
the second rib extends continuously at least over the first side wall, the upper wall, and the second side wall.

2. The substrate storing container according to claim 1, wherein
the container body further includes a hanging part by means of which the substrate storing container is suspended, and
the second rib is disposed between the first rib and the hanging part in the forward-rearward direction.

3. The substrate storing container according to claim 1, wherein the upper wall that is located at a base portion of the second rib includes a stepped portion which is oriented toward the rearward side and recesses inward in a direction orthogonal to the forward-rearward direction.

4. The substrate storing container according to claim 1, wherein a position of a top of the first rib and a position of a top of the second rib are identical with each other in a direction orthogonal to the forward-rearward direction.

5. The substrate storing container according to claim 1, wherein a distance between the first rib and the second rib in the forward-rearward direction is 10 mm to 50 mm.

6. The substrate storing container according to claim 1, wherein the second rib extends over the first side wall, the upper wall, the second side wall, and the lower wall.
